(19) United States
(12) Patent Application Publication
(10) Pub. No.: US 2024/0096821 A1
(43) Pub. Date: Mar. 21, 2024

(54) SEMICONDUCTOR STORAGE DEVICE

(71) Applicant: Kioxia Corporation, Tokyo (JP)

(72) Inventor: Kenta SASAKI, Mie Mie (JP)

(21) Appl. No.: 18/360,711

(22) Filed: Jul. 27, 2023

(30) Foreign Application Priority Data
Sep. 16, 2022 (JP) 2022-148191

(51) Int. Cl. H01L 23/00; H01L 23/528; H01L 25/065; H10B 43/10; H10B 43/20; H10B 43/35; H10B 43/40; H10B 80/00

(52) U.S. Cl. CPC H01L 23/562; H01L 23/5283; H01L 24/08; H01L 25/0657; H10B 43/10; H10B 43/20; H10B 43/35; H10B 43/40; H10B 80/00; H01L 2224/08121; H01L 2224/08145; H01L 2225/06527; H01L 2924/1431; H01L 2924/1438

(57) ABSTRACT

According to one embodiment, a semiconductor storage device includes a first chip with a substrate and a second chip. The second chip has a memory cell array with wiring layers spaced apart from each other in a first direction and a memory pillar that penetrates the wiring layers in the first direction. Connection pads are in a boundary between the first and second chips. Contacts extend in the first direction from the connection pads. An insulator layer surrounds the contacts in a plane parallel to the substrate. A first member is adjacent to the insulator layer in the plane. The insulator layer separates the first member from the first contacts, and the first member has a stress value different from a stress value of the first insulator layer.

### CROSS-REFERENCE TO RELATED APPLICATION

This application is based upon and claims the benefit of priority from Japanese Patent Application No. 2022-148191, filed Sep. 16, 2022, the entire contents of which are incorporated herein by reference.

### FIELD

Embodiments described herein relate generally to a semiconductor storage device.

### BACKGROUND

A NAND flash memory is known as a semiconductor storage device capable of storing data in a nonvolatile manner. The NAND flash memory adopts a three-dimensional memory structure for high integration and large capacity.

### BRIEF DESCRIPTION OF THE DRAWINGS

FIG. 1 is a block diagram of a memory system including a semiconductor storage device according to an embodiment.

FIG. 2 is a circuit diagram of a memory cell array in a semiconductor storage device according to an embodiment.

FIG. 3 is a cross-sectional view of a memory cell array in a semiconductor storage device according to an embodiment.

FIG. 4 is a cross-sectional view of a semiconductor storage device according to an embodiment.

FIG. 5 is a cross-sectional view of a semiconductor storage device.

FIG. 6 is a cross-sectional view of a connection pad according to an embodiment.

FIG. 7 is a cross-sectional view depicting aspects of a manufacturing method of a memory cell array in a semiconductor storage device according to an embodiment.

FIG. 8 is a top view showing the example of the manufacturing method of the memory cell array in the semiconductor storage device according to the embodiment.

FIGS. 9 to 18 are cross-sectional views depicting aspects of a manufacturing method of a memory cell array in a semiconductor storage device according to an embodiment.

FIG. 19 is a cross-sectional view of a semiconductor storage device according to a first modification example.

FIG. 20 is a cross-sectional view of a semiconductor storage device according to a first modification example.

FIG. 21 is a cross-sectional view of a semiconductor storage device according to a second modification example.

FIG. 22 is a cross-sectional view of a semiconductor storage device according to a third modification example.

FIG. 23 is a cross-sectional view depicting aspects of a manufacturing method of a memory cell array in a semiconductor storage device according to a third modification example.

### DETAILED DESCRIPTION

In general, according to one embodiment, a semiconductor storage device has a first chip including a substrate and a second chip contacting the first chip. The second chip includes a memory cell array including a plurality of first wiring layers spaced apart from each other in a first direction and a memory pillar that penetrates the plurality of first wiring layers in the first direction. A plurality of first connection pads are in a boundary region between the first chip and the second chip in the first direction. A plurality of first contacts extend in the first direction from the plurality of first connection pads. A first insulator layer surrounds the plurality of first contacts in a first plane parallel to the substrate. A first member is adjacent to the first insulator layer in the first plane. The first insulator layer separates the first member from the plurality of first contacts. The first member has a stress value different from a stress value of the first insulator layer.

Hereinafter, certain example embodiments will be described with reference to the drawings. The dimensions and ratios in the drawings are not necessarily the same as the actual ones. In the following description, elements, components, or aspects having substantially the same function and configuration are denoted by the same reference signs. However, for distinguishing instances of elements having substantially similar configurations from each other, different letters or numerals may be added as suffixes to the same reference sign.

### 1 Embodiment

A semiconductor storage device according to an embodiment will be described below.

### 1.1 Configuration

A configuration of the semiconductor storage device according to the embodiment will be described.

### 1.1.1 Memory System

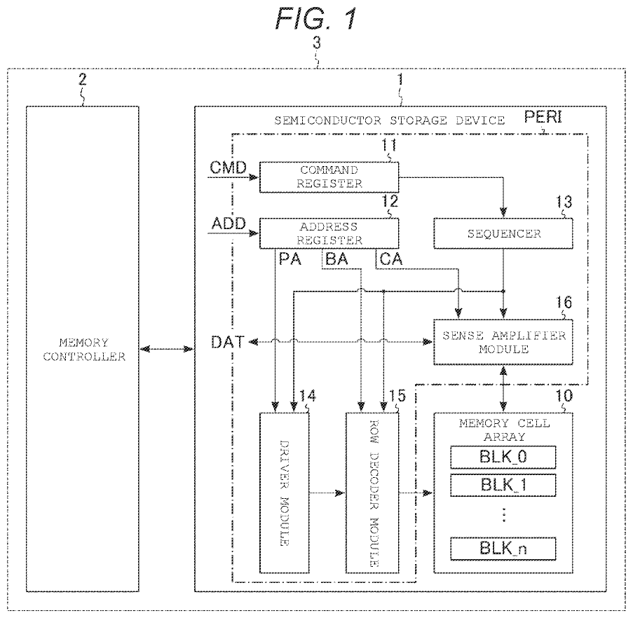

First, a configuration example of a memory system will be described with reference to FIG. 1. FIG. 1 is a block diagram showing an example of the configuration of the memory system including the semiconductor storage device according to the embodiment.

A memory system 3 is, for example, a solid-state drive (SSD) or an SD™ card. The memory system 3 can be connected to an external host device. The memory system 3 stores data from the host device. The memory system 3 also reads data for the host device and sends the read data to the host device.

The memory system 3 includes a semiconductor storage device 1 and a memory controller 2.

The semiconductor storage device 1 is, for example, a NAND flash memory. The semiconductor storage device 1 stores data in a nonvolatile manner. A case where the semiconductor storage device 1 is a NAND flash memory will be described below as an example.

The memory controller 2 is, for example, an integrated circuit device such as a system-on-a-chip (SoC). The memory controller 2 writes data to the semiconductor storage device 1 based on a request from the host device. The memory controller 2 reads data from the semiconductor storage device 1 based on a request from the host device. The memory controller 2 also transmits data read from the semiconductor storage device 1 to the host device.

Communication between the semiconductor storage device 1 and the memory controller 2 conforms to, for example, a single data rate (SDR) interface, a toggle double data rate (DDR) interface, or an open NAND flash interface (ONFI).

### 1.1.2 Semiconductor Storage Device

The internal configuration of the semiconductor storage device 1 will be described with reference to FIG. 1. The semiconductor storage device 1 includes a memory cell array 10 and a peripheral circuit PERI. The peripheral circuit PERI includes a command register 11, an address register 12, a sequencer 13, a driver module 14, a row decoder module 15, and a sense amplifier module 16, for example.

The memory cell array 10 includes a plurality of blocks BLK (BLK_0 to BLK_n, n is an integer equal to or larger than 1). Each block BLK is a set of memory cells capable of storing data in a nonvolatile manner. The block BLK can be used as a data erasing unit, for example. A plurality of bit lines and a plurality of word lines are provided in the memory cell array 10. Each memory cell is associated with one bit line and one word line.

The command register 11 stores a command CMD received from the memory controller 2 for the semiconductor storage device 1. The command CMD includes, for example, an instruction to cause the sequencer 13 to perform a read operation, a write operation, an erasing operation, or the like.

The address register 12 stores address information ADD received from the memory controller 2 for the semiconductor storage device 1. The address information ADD includes, for example, a page address PA, a block address BA, and a column address CA. The page address PA, the block address BA, and the column address CA can be used to select the appropriate word line, block BLK, and bit line, respectively.

The sequencer 13 controls the operation of the semiconductor storage device 1 as a whole. The sequencer 13 performs functions for a read operation, a write operation, or an erasing operation based on the command CMD stored in the command register 11.

The driver module 14 generates voltages used in the read operation, the write operation, the erasing operation, and the like. The driver module 14 applies the generated voltage to a signal line corresponding to the selected word line, based on the page address PA stored in the address register 12, for example.

The row decoder module 15 selects a block BLK in the corresponding memory cell array 10 based on the block address BA stored in the address register 12. The row decoder module 15 transfers the voltage applied to the signal line corresponding to the selected word line to the selected word line in the selected block BLK.

The sense amplifier module 16 transfers write data DAT received from the memory controller 2 to the memory cell array 10 in a write operation. The sense amplifier module 16 also performs determination of data stored in the memory cells based on the voltage on a bit line in a read operation. The sense amplifier module 16 reads the determination result and transfers the determination result to the memory controller 2 as read data DAT.

### 1.1.3 Circuit Configuration of Memory Cell Array

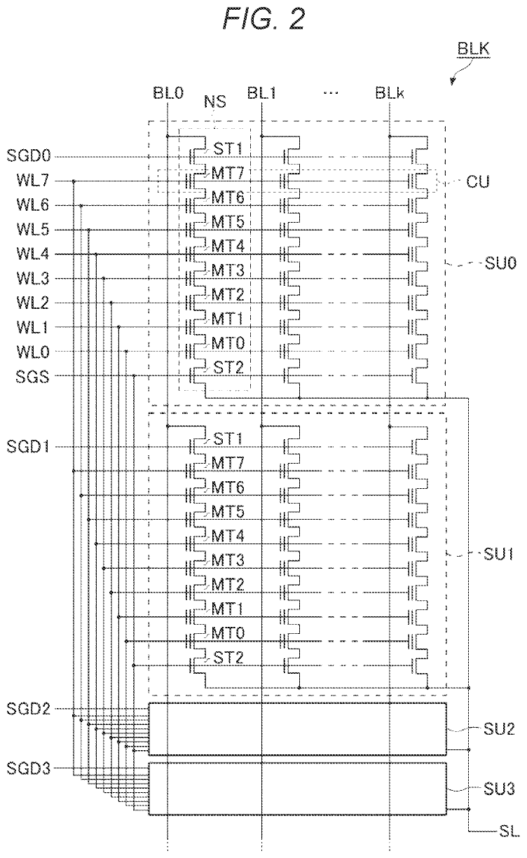

An example of a circuit configuration of the memory cell array 10 will be described with reference to FIG. 2. FIG. 2 is a circuit diagram showing the example of the circuit configuration of the memory cell array in the semiconductor storage device according to the embodiment. FIG. 2 shows one block BLK among a plurality of blocks BLK in the memory cell array 10. In the example shown in FIG. 2, the block BLK includes four string units SU0, SU1, SU2, and SU3.

Each string unit SU includes a plurality of NAND strings NS associated with bit lines BL0 to BLk (k is an integer of 1 or more). Each NAND string NS includes, for example, memory cell transistors MT0 to MT7 and select transistors ST1 and ST2. Each of the memory cell transistors MT0 to MT7 includes a control gate and a charge storage film. Each of the memory cell transistors MT0 to MT7 stores data in a nonvolatile manner. The select transistors ST1 and ST2 are used to select a string unit SU in various operations. In the following description, when the bit lines BL0 to BLk are not distinguished from each other, each of the bit lines BL0 to BLk is simply referred to as a bit line BL. When the memory cell transistors MT0 to MT7 are not distinguished from each other, each of the memory cell transistors MT0 to MT7 is simply referred to as a memory cell transistor MT.

The memory cell transistors MT0 to MT7 in each NAND string NS are connected in series. A first end of the select transistor ST1 is connected to the bit line BL associated with the select transistor ST1. A second end of the select transistor ST1 is connected to one end of the memory cell transistors MT0 to MT7 connected in series. A first end of the select transistor ST2 is connected to the other end of the memory cell transistors MT0 to MT7 connected in series. A second end of the select transistor ST2 is connected to a source line SL.

The control gates of the memory cell transistors MT0 to MT7 in the same block BLK are each connected to word lines WL0 to WL7, respectively. The gates of the select transistors ST1 in the respective string units SU0 to SU3 are connected to select gate lines SGD0 to SGD3. On the other hand, gates of the plurality of select transistors ST2 are each connected in common to a select gate line SGS. However, the embodiment is not limited to this, and the gates of the plurality of select transistors ST2 may be connected to a plurality of select gate lines SGS that are different for each string unit SU. In the following description, when the word lines WL0 to WL7 are not distinguished from each other, each of the word lines WL0 to WL7 is simply referred to as a word line WL. When the select gate lines SGD0 to SGD3 are not distinguished from each other, each of the select gate lines SGD0 to SGD3 is simply referred to as a select gate line SGD.

Different column addresses are allocated to the respective bit lines BL0 to BLk. Each of the bit lines BL is shared by the NAND strings NS to which the same column address is allocated among the plurality of blocks BLK. The word lines WL0 to WL7 are provided for each block BLK. The source line SL is shared among, for example, the plurality of blocks BLK.

A set of memory cell transistors MT connected to a common word line WL in the same string unit SU is referred to as, for example, a “cell unit CU”. For example, a storage capacity of the cell unit CU that includes the plurality of memory cell transistors MT, each of which stores 1 bit data, is defined as “one page data”. The cell unit CU may have a storage capacity equal to or larger than two page data according to the number of bits of data stored in the memory cell transistor MT.

The circuit configuration of the memory cell array 10 is not limited to the configuration described above. For example, each block BLK may include any number of string units SU. Each NAND string NS may include any number of memory cell transistors MT and select transistors ST1 and ST2.

### 1.1.4 Structure of Memory Cell Array

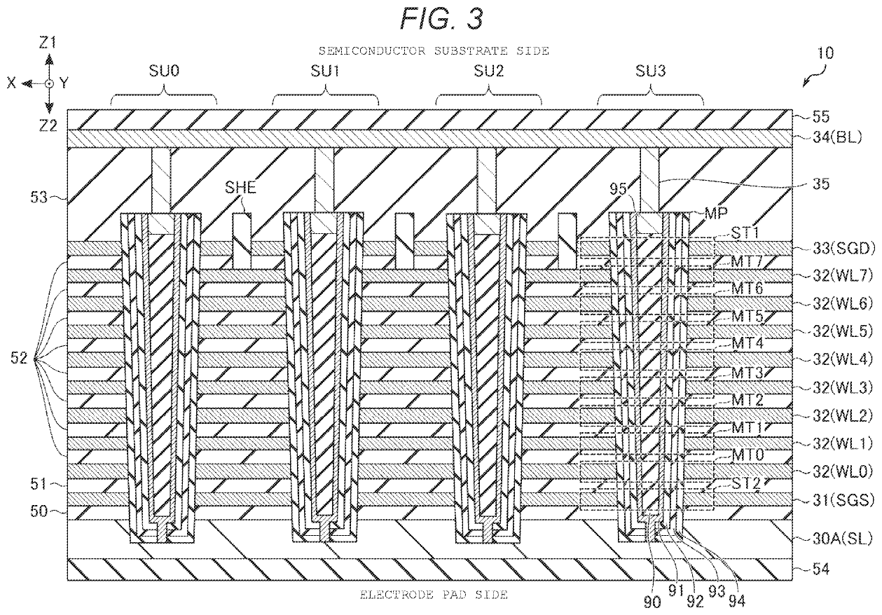

Next, the structure of the memory cell array 10 will be described with reference to FIG. 3. FIG. 3 shows an example of a cross-sectional structure of the memory cell array 10 of the semiconductor storage device 1 according to the embodiment.

In the drawings referred to below, an X-direction corresponds to an extending direction (length dimension) of the bit lines BL, and a Y-direction corresponds to an extending direction (length dimension) of the word lines WL. A Z1 direction corresponds to a direction from an electrode pad of the semiconductor storage device 1 toward a semiconductor substrate, and a Z2 direction corresponds to a direction from the semiconductor substrate of the semiconductor storage device 1 toward the electrode pad. The Z1 direction and the Z2 direction are each directions along a Z-direction. In the following description, a surface and an end on the electrode pad side of any element may be referred to as a first surface and a first end, respectively. Similarly, a surface and an end on the semiconductor substrate side of an element can be referred to as a second surface and a second end, respectively.

The memory cell array 10 includes conductor layers 30A, 31, 33, 34, and 35, a plurality of conductor layers 32, insulator layers 50, 51, and 53, a plurality of insulator layers 52, and a plurality of memory pillars MP. FIG. 3 shows four memory pillars MP among the plurality of memory pillars MP. FIG. 3 also shows a case with eight conductor layers 32 and eight insulator layers 52. The memory cell array 10 is provided between the electrode pads of the semiconductor storage device 1 and the semiconductor substrate in the Z-direction.

The conductor layer 30A is formed, for example, in a plate shape extending along an XY plane. The conductor layer 30A is used as the source line SL. The conductor layer 30A is made of a conductive material. The conductive material is, for example, a metal material or an N-type semiconductor doped with impurities.

The insulator layer 50 is stacked on the second surface of the conductor layer 30A. The conductor layer 31 is stacked on the second surface of the insulator layer 50. The conductor layer 31 is formed, for example, in a plate shape extending along the XY plane. The conductor layer 31 is used as the select gate line SGS. The conductor layer 31 comprises tungsten, for example.

The insulator layer 51 is stacked on the second surface of the conductor layer 31. The eight conductor layers 32 and the eight insulator layers 52 are stacked on the second surface of the insulator layer 51 in alternating order in the Z1 direction. Each conductor layer 32 is formed, for example, in a plate shape extending along the XY plane. The eight conductor layers 32 are used as the word lines WL0 to WL7 in order from the conductor layer 31 side in the Z1 direction, respectively. The conductor layer 32 comprises tungsten, for example.

The conductor layer 33 is stacked on the second surface of the insulator layer 52 closest to the semiconductor substrate among the eight insulator layers 52. The conductor layer 33 is formed, for example, in a plate shape extending along the XY plane. The conductor layer 33 is used as the select gate line SGD. The conductor layer 33 comprises tungsten, for example. The conductor layers 33 are electrically insulated for each string unit SU by members SHE.

The insulator layer 53 is stacked on the second surface of the conductor layer 33. The conductor layer 34 is stacked on the second surface of the insulator layer 53. The conductor layer 34 is provided to extend in the X-direction. The conductor layer 34 functions as a bit line BL.

The stacked structure including the conductor layers 30A, 31, 33, and 34, the eight conductor layers 32, the insulator layers 50, 51, and 53, and the eight insulator layers 52 is surrounded by an insulator layer. FIG. 3 shows an insulator layer 54 in contact with the first surface of the conductor layer 30A and an insulator layer 55 in contact with the second surface of the conductor layer 34. Although not shown in FIG. 3, the conductor layer 30A is electrically connected to the peripheral circuit PERI, for example, via a conductor layer on the electrode pad side of the conductor layer 30A. Although not specifically depicted in FIG. 3, the conductor layer 34 can be electrically connected to the peripheral circuit PERI, for example, via a conductor layer on the semiconductor substrate side of the conductor layer 34.

A plurality of memory pillars MP are provided to extend in the Z1 direction on the electrode pad side of the conductor layer 34. The plurality of memory pillars MP penetrate the conductor layers 31 and 33 and the eight conductor layers 32.

Each of the memory pillars MP includes, for example, a core member 90, a semiconductor film 91, a tunnel insulating film 92, a charge storage film 93, a block insulating film 94, and a semiconductor portion 95.

The core member 90 is provided to extend in the Z1 direction. The first end of the core member 90 is located closer to the semiconductor substrate than the conductor layer 30A, for example. The second end of the core member 90 is located closer to the semiconductor substrate than the conductor layer 33, for example. The core member 90 comprises, for example, silicon oxide.

The semiconductor film 91 covers the side surface of the core member 90. The first end of the semiconductor film 91 covers the first end of the core member 90. The first end of the semiconductor film 91 is in contact with the conductor layer 30A. The second end of the semiconductor film 91 is located closer to the semiconductor substrate than the second end of the core member 90. The semiconductor film 91 comprises polysilicon, for example.

The tunnel insulating film 92 covers the side surface of the semiconductor film 91. The second end of the tunnel insulating film 92 is located at a height equal to a height of the second end of the semiconductor film 91. The tunnel insulating film 92 comprises silicon oxide, for example.

The charge storage film 93 covers the side surface of the tunnel insulating film 92. The second end of the charge storage film 93 is located at a height equal to heights of the second end of the semiconductor film 91 and the second end of the tunnel insulating film 92. The charge storage film 93 includes an insulator capable of storing charges. The insulator can be, for example, silicon nitride.

The block insulating film 94 covers the side surface of the charge storage film 93. The second end of the block insulating film 94 is located at a height equal to heights of the second end of the semiconductor film 91, the second end of the tunnel insulating film 92, and the second end of the charge storage film 93. The block insulating film 94 comprises silicon oxide, for example.

The semiconductor portion 95 covers the second surface of the core member 90. The side surface of the semiconductor portion 95 is covered with the second end of the semiconductor film 91.

A conductor layer 35 is in contact with each of the semiconductor portions 95 and the conductor layers 34 and is between the semiconductor portion 95 and the conductor layer 34 in the Z-direction.

A portion of the memory pillars MP at an intersection with conductor layer 31 functions as a select transistor ST2. A portion of the memory pillars MP at an intersection with a conductor layer 32 functions as a memory cell transistor MT. A portion of the memory pillars MP at an intersection with conductor layer 33 functions as a select transistor ST1. The semiconductor film 91 functions as the channel of the memory cell transistors MT0 to MT7 and the select transistors ST1 and ST2. The charge storage film 93 functions as a charge storage layer of the memory cell transistors MT.

### 1.1.5 Structure of Semiconductor Storage Device

An example of the structure of the semiconductor storage device 1 according to the embodiment will be described below.

### 1.1.5.1 Cross-Sectional Structure of Semiconductor Storage Device

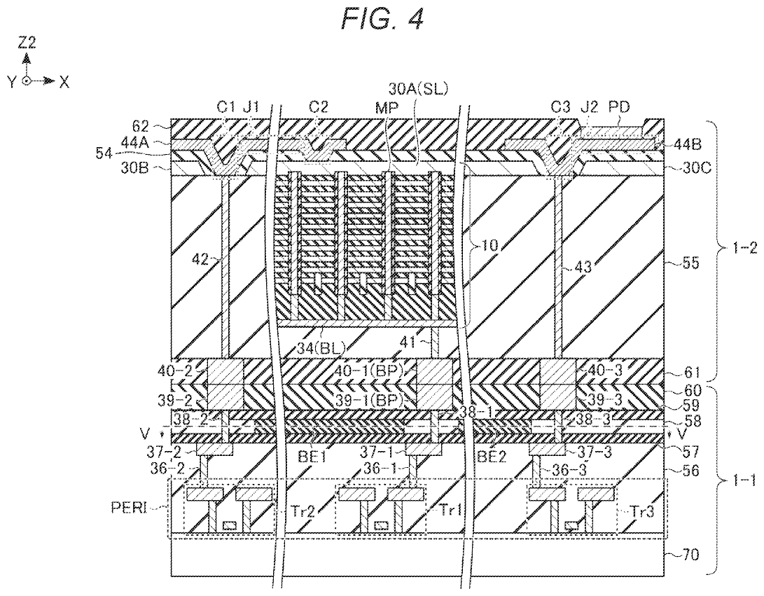

A cross-sectional structure of the semiconductor storage device 1 according to the embodiment will be described with reference to FIG. 4. FIG. 4 is a cross-sectional view showing an example of the cross-sectional structure of the semiconductor storage device according to the embodiment in an XZ plane. FIG. 4 shows the cross-sectional structure of a portion of the semiconductor storage device 1.

The semiconductor storage device 1 has a structure in which a circuit chip 1-1 and a memory chip 1-2 are bonded to each other.

First, the cross-sectional structure of the circuit chip 1-1 will be described.

The circuit chip 1-1 includes a semiconductor substrate 70, a peripheral circuit PERI, a plurality of conductor layers 36, 37, 38, and 39, burying members BE1 and BE2 (also referred to as buried members BE), and insulator layers 56, 57, 58, 59 and 60. A case where the semiconductor storage device 1 includes two burying members BE will be described below, but the embodiment is not limited to this. The semiconductor storage device 1 may include just one burying member BE, or may include three or more burying members BE.

The insulator layer 56 is provided on the first surface of the semiconductor substrate 70. The insulator layer 56 comprises, for example, silicon oxide. The peripheral circuit PERI and the plurality of conductor layers 36 and 37 are provided in the insulator layer 56.

The peripheral circuit PERI is provided on the first surface of the semiconductor substrate 70. FIG. 4 shows three transistors Tr1, Tr2, and Tr3 as an example of the configuration included in the peripheral circuit PERI. The three transistors Tr1, Tr2, and Tr3 are connected to, for example, the bit line BL, the source line SL, and the electrode pad, respectively.

The plurality of conductor layers 36 includes conductor layers 36-1, 36-2, and 36-3. The conductor layers 36-1, 36-2, and 36-3 are respectively connected to the transistors Tr1, Tr2, and Tr3 in the peripheral circuit PERI. Each of the plurality of conductor layers 36 functions as a columnar contact.

The plurality of conductor layers 37 includes conductor layers 37-1, 37-2, and 37-3. The conductor layers 37-1, 37-2, and 37-3 are connected to the first surfaces of the conductor layers 36-1, 36-2, and 36-3, respectively.

The insulator layers 57, 58, and 59 are provided in this order in the Z2 direction on the first surface of the insulator layer 56 and on the first surfaces of the plurality of conductor layers 37, respectively. Each of the insulator layers 57, 58, and 59 is formed, for example, in a plate shape extending along the XY plane. The insulator layer 57 comprises, for example, silicon carbide with nitrogen. The insulator layer 58 comprises, for example, silicon oxide. The insulator layer 59 comprises, for example, silicon nitride. A plurality of conductor layers 38 and the burying members BE1 and BE2 are provided in portions where the insulator layers 57, 58 and 59 are provided.

Each of the conductor layers 38 intersects the insulator layers 57, 58, and 59. Thus, each of the plurality of conductor layers 38 is surrounded by the respective insulator layers 57 to 59. The first surface of each of the conductor layers 38 is located at a height equal to the height of the first surface of the insulator layer 59. The second surface of each of the conductor layers 38 is located at a height equal to the height of the second surface of the insulator layer 57. The plurality of conductor layers 38 includes conductor layers 38-1, 38-2, and 38-3. The conductor layers 38-1, 38-2, and 38-3 are connected to the first surfaces of the conductor layers 37-1, 37-2, and 37-3, respectively. Each of the conductor layers 38 functions as a columnar contact.

The burying members BE1 and BE2 are spaced apart from each other in the X-direction. The first surface of each burying member BE is located at a height equal to the height of the first surface of the insulator layer 58. The second surface of each burying member BE is located at a height equal to the height of the second surface of the insulator layer 58.

Each burying member BE is, for example, a high compressive stress member or a tensile stress member.

A high compressive stress member has compressive internal stress higher than, for example, the insulator layer 58. That is, the high compressive stress member has an internal compressive stress value higher than a film of silicon oxide, for example. The tensile stress member has internal tensile stress. In the semiconductor storage device 1 in which a high compressive stress member or a tensile stress member is applied as the burying member BE, possible differences other than the type of the burying member BE used will be described later. As described above, each burying member BE has an internal stress value different from the internal stress value of the insulator layer 58.

More specifically, the high compressive stress member comprises silicon nitride formed by physical vapor deposition (PVD) such as sputtering, for example. The high compressive stress member has internal compressive stress of −300 MPa or less (absolute value of 300 MPa or more), for example. The tensile stress member comprises silicon nitride formed by chemical vapor deposition (CVD), for example. The tensile stress member has, for example, internal tensile stress having an absolute value of 300 MPa or more. Silicon nitride formed by PVD has a lower hydrogen content than silicon nitride formed by CVD. Thus, for example, it is possible to distinguish between silicon nitride formed by PVD and silicon nitride formed by CVD by secondary ion mass spectrometry.

As the high compressive stress member, for example, a material obtained by doping impurities such as carbon or boron to silicon nitride formed by CVD may be used. A material different from silicon nitride may be used as the high compressive stress member or the tensile stress member in other examples.

An insulator layer 60 is provided on the first surfaces of the insulator layer 59 and the plurality of conductor layers 38. The insulator layer 60 comprises, for example, silicon oxide. A plurality of conductor layers 39 are provided in the same layer as the insulator layer 60. The plurality of conductor layers 39 comprise, for example, copper.

The plurality of conductor layers 39 includes conductor layers 39-1, 39-2, and 39-3. The conductor layers 39-1, 39-2, and 39-3 are connected to the first surfaces of the conductor layers 38-1, 38-2, and 38-3, respectively. Each of the conductor layers 39 is provided such that the first surface of the conductor layer 39 and the first surface of the circuit chip 1-1 are flush with each other. Each of the conductor layers 39 functions as a connection pad BP for electrically connecting the circuit chip 1-1 and the memory chip 1-2.

Next, the cross-sectional structure of the memory chip 1-2 will be described.

The memory chip 1-2 includes conductor layers 30B, 30C, 41, 42, 43, 44A, and 44B, a plurality of conductor layers 40, insulator layers 54, 55, 61, and 62, a memory cell array 10, and an electrode pad PD.

In the memory chip 1-2, the insulator layer 61 is provided on the first surface of the circuit chip 1-1. The insulator layer 61 comprises, for example, silicon oxide. A plurality of conductor layers 40 are provided in the same layer as the insulator layer 61. The plurality of conductor layers 40 contain, for example, copper.

On the second surface of the memory chip 1-2, any of the plurality of conductor layers 40 functioning as connection pads BP can be provided on the first surface of each of the conductor layers 39 of the circuit chip 1-1. The plurality of conductor layers 40 includes conductor layers 40-1, 40-2, and 40-3. The conductor layers 40-1, 40-2, and 40-3 are connected to the first surfaces of the conductor layers 39-1, 39-2, and 39-3, respectively. With such configurations, the circuit chip 1-1 and the memory chip 1-2 are electrically connected by the plurality of conductor layers 39 and 40.

The insulator layer 55 is provided on the first surfaces of the insulator layer 61 and the plurality of conductor layers 40. The insulator layer 55 comprises, for example, silicon oxide. The conductor layers 41, 42, and 43 and a portion of the memory cell array 10 are provided in the insulator layer 55.

The memory cell array 10 is provided such that the conductor layer 34 is disposed on the semiconductor substrate 70 side and the conductor layer 30A is disposed on the electrode pad PD side. The memory cell array 10 is provided, for example, such that the second surface of the conductor layer 30A is located at a height equal to the height of the first surface of the insulator layer 55. That is, the conductor layers 31 and 33 to 35, the eight conductor layers 32, the insulator layers 50, 51, and 53, the eight insulator layers 52, a plurality of members SHE, a plurality of memory pillars MP, and the like in the memory cell array 10 are provided in the insulator layer 55.

The conductor layer 41 is provided on the first surface of the conductor layer 40-1. The conductor layer 41 functions as a columnar contact. The first surface of conductor layer 41 is connected to the second surface of conductor layer 34. As a result, the conductor layer 40-1 is connected to the bit line BL through the conductor layer 41.

The conductor layer 42 is provided on the first surface of the conductor layer 40-2. The conductor layer 42 functions as a columnar contact. The conductor layer 42 penetrates the insulator layer 55 in the Z-direction.

The conductor layer 43 is provided on the first surface of the conductor layer 40-3. The conductor layer 43 functions as a columnar contact. The conductor layer 43 penetrates the insulator layer 55 in the Z-direction.

The conductor layer 30A in the memory cell array 10 includes, for example, portions provided on the first surface of the insulator layer 50 of the memory cell array 10, on the first surface of each of the memory pillars MP, and on the first surface of the insulator layer 55.

The conductor layer 30B is provided on the first surface of the insulator layer 55. The conductor layer 30C is provided on the first surface of the insulator layer 55.

The conductor layers 30A and 30B, the conductor layers 30A and 30C, and the conductor layers 30B and 30C are each electrically insulated from each other. The conductor layers 30A, 30B, and 30C are provided in the same layer.

The conductor layers 44A and 44B are provided closer to the electrode pad PD than the insulator layer 55. The conductor layers 44A and 44B function as wiring layers. The conductor layers 44A and 44B contain, for example, aluminum. The conductor layers 44A and 44B are electrically insulated from each other.

The conductor layer 44A extends in the X-direction. The conductor layer 44A includes portions C1, J1, and C2. The portions C1, J1, and C2 are arranged in this order along the X-direction. The portion C1 is in contact with the first surface of the conductor layer 42 and a region of the first surface of the insulator layer 55 surrounding the first surface of the conductor layer 42. The portion C2 is in contact with at least a portion of the first surface of the conductor layer 30A. The portion J1 electrically connects the portions C1 and C2 to each other at positions not in contact with the first surfaces of the conductor layers 30A and 42. With such a configuration, the conductor layer 44A electrically connects the conductor layers 30A and 42 to each other.

The conductor layer 44B extends in the X-direction. The conductor layer 44B includes portions C3 and J2. The portion C3 is in contact with the first surface of the conductor layer 43 and a region of the first surface of the insulator layer 55 surrounding the first surface of the conductor layer 43. The portion J2 is connected to the portion C3 at a position not in contact with the first surfaces of conductor layers 30C and 43.

The electrode pad PD is provided on the first surface of the portion J2 of the conductor layer 44B. The electrode pad PD may be connected to a mounting substrate, an external device, or the like by, for example, a bonding wire, a solder ball, a metal bump, or the like. The electrode pads PD contain, for example, copper.

The insulator layer 54 is provided up to the height of the second surfaces of the portions J1 and J2 in regions on the first surface of each of the insulator layer 55 and the conductor layers 30A, 30B, and 30C not in contact with the conductor layers 44A and 44B. The insulator layer 54 comprises, for example, silicon oxide. For example, the insulator layer 54 electrically insulates, for example, the conductor layers 44A and 30B from each other, electrically insulates the conductor layers 44B and 30A from each other, and electrically insulates the conductor layers 44B and 30C from each other.

The insulator layer 62 is provided in regions on the first surface of the conductor layer 44A and on the first surface of the insulator layer 54 not in contact with the conductor layers 44A and 44B, and in a region other than a region in which the electrode pad PD is provided on the first surface of the conductor layer 44B. The insulator layer 62 functions as a passivation film. The insulator layer 62 comprises, for example, silicon nitride, a resin material, or the like.

### 1.1.5.2 Structure in Same Layer as Burying Member

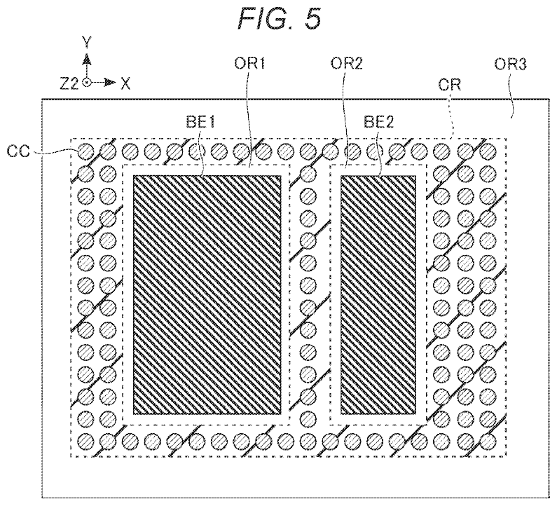

The burying members BE1 and BE2 and the structure included in the same layer as the burying members BE1 and BE2 will be described with reference to FIG. 5. FIG. 5 is a cross-sectional view of the semiconductor storage device at the height equal to the height of V-V line along the Z-direction in FIG. 4, showing an example of a cross-sectional structure of the semiconductor storage device according to the embodiment in the XY plane. FIG. 5 shows the cross-sectional structure of the entire semiconductor storage device 1.

The semiconductor storage device 1 is divided into a region CR and a plurality of regions OR in the cross section shown in FIG. 5. In FIG. 5, the region CR is a hatched region surrounded by dotted lines.

The region CR is a region in which a plurality of wirings CC are provided. The plurality of wirings CC include a plurality of conductor layers 38. Although not specifically depicted in FIG. 4, the plurality of wirings CC also include contacts that electrically connect the word lines WL0 to WL7 and the select gate lines SGS and SGD to the peripheral circuit PERI. The plurality of wirings CC and a first portion of the insulator layer 58 are provided in the region CR, for example. The first portion of the insulator layer 58 surrounds each of the wirings CC. As a result, each of the wirings CC can be provided to be spaced apart (isolated) from the burying member BE.

The regions OR are a plurality of regions other than the region CR in the cross section of the semiconductor storage device 1 shown in FIG. 5. For example, the burying members BE1 and BE2 and a second portion of the insulator layer 58 are provided in the plurality of regions OR. The second portion of the insulator layer 58 is, for example, a portion of the insulator layer 58 other than the first portion of the insulator layer 58.

The regions OR, in the example shown in FIG. 5, include the regions OR1, OR2, and OR3. Each of the regions OR1 and OR2 is surrounded by the region CR. Each of the regions OR1 and OR2 is provided in a rectangular shape having sides parallel to the X-direction and sides parallel to the Y-direction, for example. The region OR3 is a portion surrounding the region CR.

Regarding the burying members BE1 and BE2, the burying members BE1 and BE2 are, in the depicted example, in a rectangular shape having sides parallel to the X-direction and sides parallel to the Y-direction. The burying member BE1 is disposed in the region OR1. The burying member BE2 is disposed in the region OR2.

The burying members BE1 and BE2 may overlap, when viewed in the Z-direction, at least a portion of the semiconductor storage device 1 in which warping is likely to occur. The portion in which the warping is more likely to occur is, for example, the memory cell array 10. In the embodiment, a portion of the burying member BE1 overlaps the memory cell array 10.

The case where the burying member BE is provided in each region OR surrounded by the region CR has been described, but the embodiment is not limited to this. The burying member BE may be disposed in the region OR3 outside the region CR.

FIG. 5 shows the case where the semiconductor storage device 1 includes one region CR, but the embodiment is not limited to this. The semiconductor storage device 1 may include two or more regions CR.

FIG. 5 shows the case where the semiconductor storage device 1 includes two regions OR surrounded by the region CR, but the embodiment is not limited to this. The semiconductor storage device 1 may have no region OR surrounded by the region CR or may include just one region OR or may include three or more regions OR surrounded by the region CR.

The shape of each region OR surrounded by the region CR is not limited to a rectangular shape. Each region OR may be provided in any polygonal shape, for example. The shape of each burying member BE is not limited to a rectangular shape, similarly to the shape of each region OR. Each burying member BE may also be provided in a polygonal shape, for example.

In the example shown in FIG. 5, each burying member BE is surrounded by the second portion of the insulator layer 58. That is, each burying member BE is not in contact with the region CR. However, the embodiment is not limited to this. A burying member BE may be provided to be in contact with the region CR. That is, for example, the burying members BE1 and BE2 may be provided over the entire regions OR1 and OR2, respectively. As described above, in the region CR, each of the plurality of wirings CC is surrounded by the first portion of the insulator layer 58. Thus, each of the plurality of wirings CC is not in contact with the burying members BE1 and BE2.

### 1.1.5.3 Cross-sectional Structure of Connection Pad

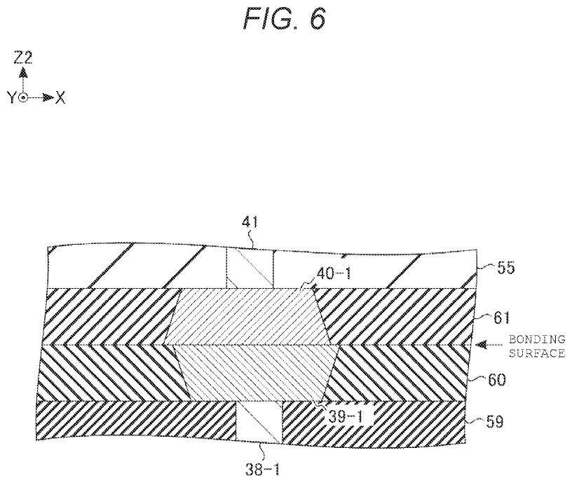

Next, a cross-sectional structure of the connection pad BP will be described with reference to FIG. 6. FIG. 6 is a cross-sectional view showing an example of the cross-sectional structure of the connection pad BP according to the embodiment. A portion at which the conductor layer 39-1 is connected with the conductor layer 40-1 will be described below, but the same applies to a portion at which each of the other plurality of conductor layers 39 is connected with the conductor layer 40 corresponding to this conductor layer 39.

On the bonding surface where the circuit chip 1-1 and the memory chip 1-2 are bonded to each other, the area of the conductor layer 39-1 is substantially equal to the area of the conductor layer 40-1, for example. In such a case, when copper is used for the conductor layers 39-1 and 40-1, the copper of the conductor layer 39-1 and the copper of the conductor layer 40-1 are integrated, and thus it may be difficult to recognize the boundaries between the coppers. However, it is possible to recognize bonding by distortion in a shape in which the conductor layer 39-1 and the conductor layer 40-1 are bonded to each other, due to misalignment in bonding, and to recognize bonding due to misalignment of a copper barrier metal (occurrence of discontinuous portions at the side surfaces).

When the conductor layers 39-1 and 40-1 are formed by the damascene method, each side surface has a tapered shape. As a result, the side wall of the conductor layer 39-1 and the side wall of the conductor layer 40-1 do not form a straight line. Therefore, the shape of the cross section along the Z-direction at the portion where the conductor layers 39-1 and 40-1 are bonded to each other is non-rectangular.

Also, when the conductor layers 39-1 and 40-1 are bonded to each other, a structure in which the bottom surface, the side surface, and the upper surface of copper forming the conductor layers 39-1 and 40-1 are covered with barrier metal is made. On the other hand, in a general wiring layer using copper, an insulator layer (silicon nitride, silicon carbide containing nitrogen, and the like) having a function of preventing oxidation of copper is provided on the upper surface of copper, and a barrier metal is not provided. Therefore, it is possible to distinguish the conductor layers 39-1 and 40-1 from a general wiring layer even when there is no misalignment in bonding.

### 1.2 Manufacturing Method of Semiconductor Storage Device

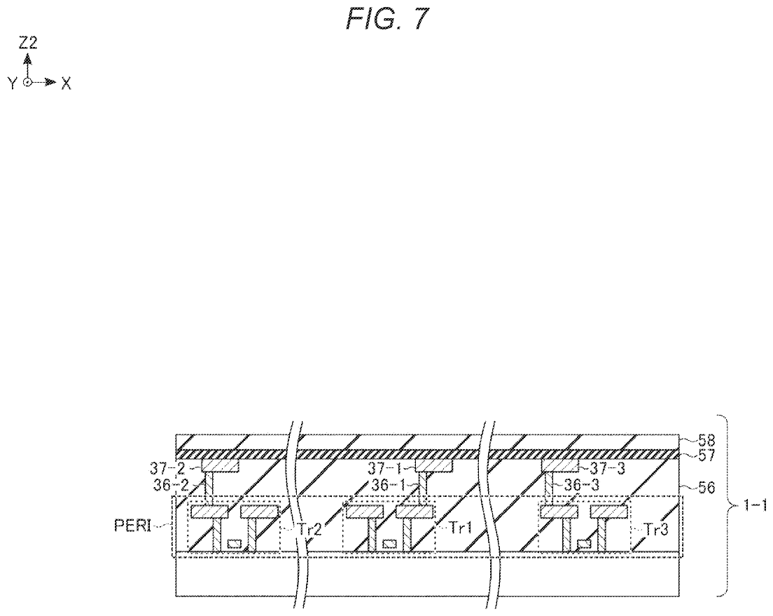

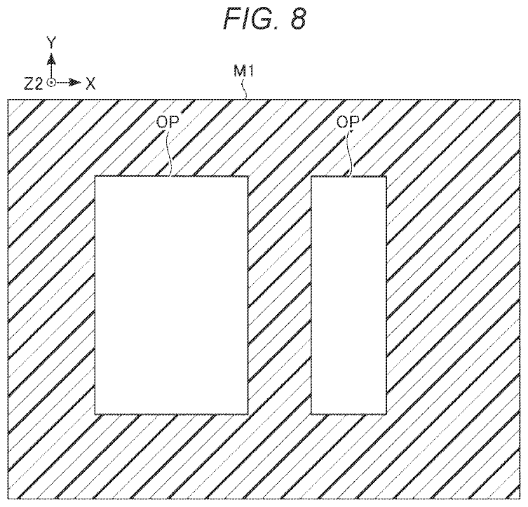

A manufacturing method of the semiconductor storage device 1 will be described with reference to FIGS. 7 to 18. FIGS. 7 and 9 to 18 are cross-sectional views showing an example of a structure in the middle of manufacturing the memory cell array 10 in the semiconductor storage device 1 according to the embodiment. The cross-sectional views shown in FIGS. 7 and 9 to 18 show regions corresponding to FIG. 4. FIG. 8 is a top view showing a mask for forming regions corresponding to FIG. 5.

First, as shown in FIG. 7, a peripheral circuit PERI and a plurality of conductor layers 36 and 37 are formed on the first surface of a semiconductor substrate 70. An insulator layer 56 is formed up to a height equal to the height of the first surface of each of a plurality of conductor layers 37 to bury the peripheral circuit PERI and the plurality of conductor layers 36 and 37. Insulator layers 57 and 58 are formed in this order in the Z2 direction on the first surfaces of the plurality of conductor layers 37 and the first surface of the insulator layer 56.

Then, as shown in FIG. 8, a mask M1 including two openings OP is formed on the first surface of the formed insulator layer 58. The two openings OP are provided corresponding to the burying members BE1 and BE2.

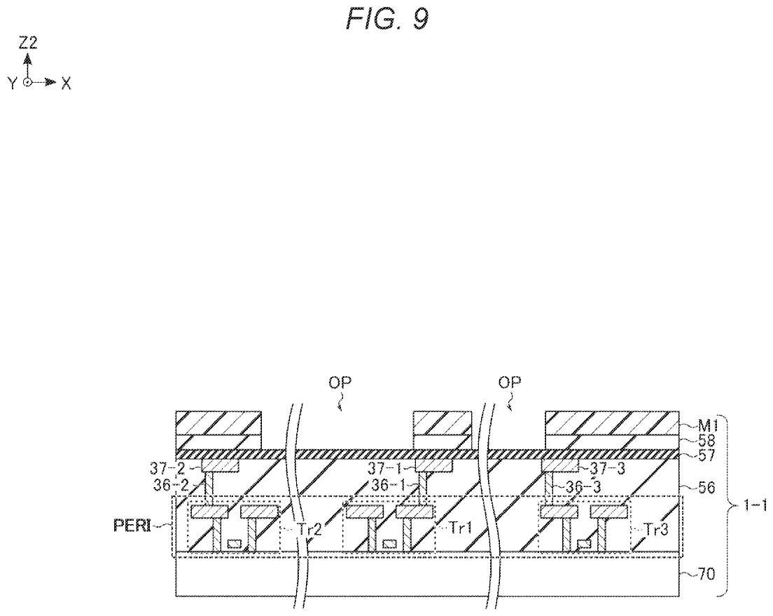

As shown in FIG. 9, by anisotropic etching using the formed mask M1, regions of the insulator layer 58 corresponding to burying members BE1 and BE2 are removed. The anisotropic etching in this process is, for example, reactive ion etching (RIE). Then, the mask M1 is removed.

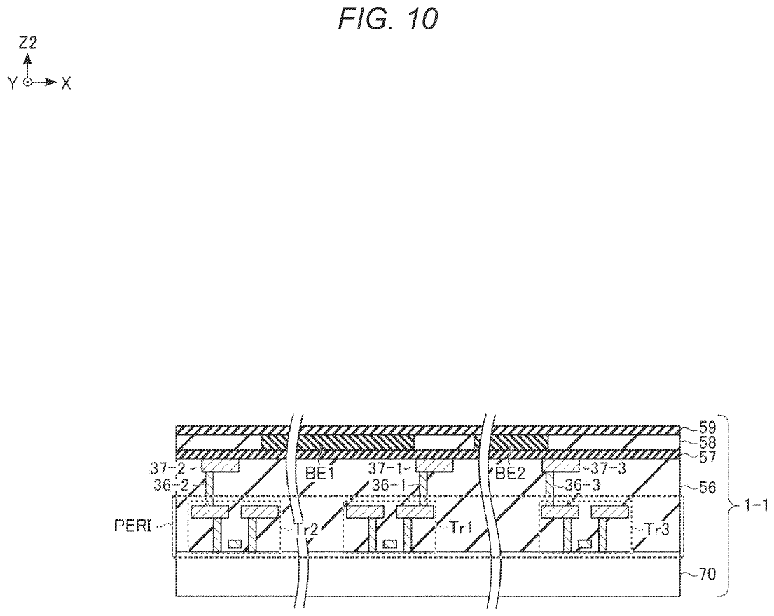

Then, spaces obtained by removal by the anisotropic etching using the mask M1 are buried with a burying member BE. When the burying member BE to be formed is silicon nitride functioning as a high compressive stress member, the burying member BE is formed by PVD, for example. When the burying member BE to be formed is silicon nitride functioning as a tensile stress member, the burying member BE is formed by CVD, for example. The upper surface of the burying member BE material is planarized by, for example, chemical mechanical polishing (CMP). Thus, the burying members BE1 and BE2 are formed as shown in FIG. 10. An insulator layer 59 is formed on the first surface of each of the burying members BE1 and BE2 and the insulator layer 58.

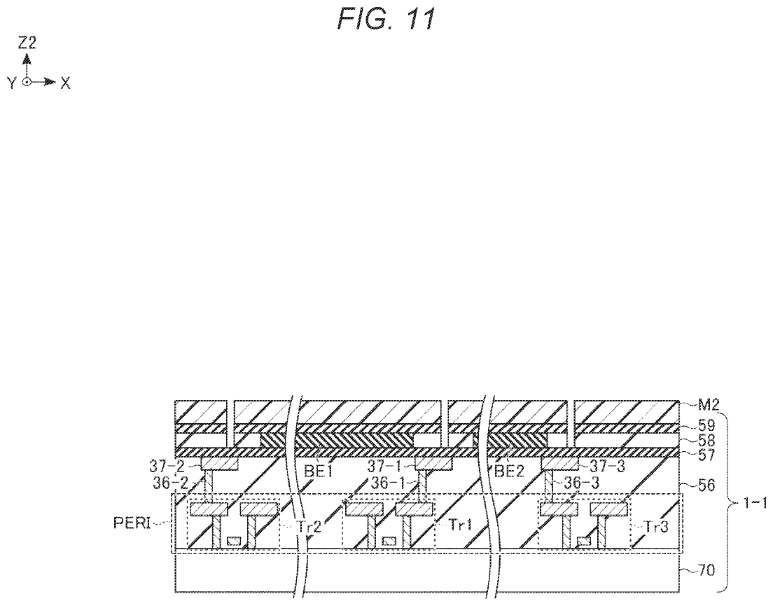

Then, as shown in FIG. 11, by anisotropic etching using a mask M2 including openings corresponding to the plurality of conductor layers 38, portions in the same layer as the insulator layers 58 and 59 are removed in a region in which a plurality of conductor layers 38 are to be formed. Anisotropic etching in this process is, for example, RIE. Then, the mask M2 is removed.

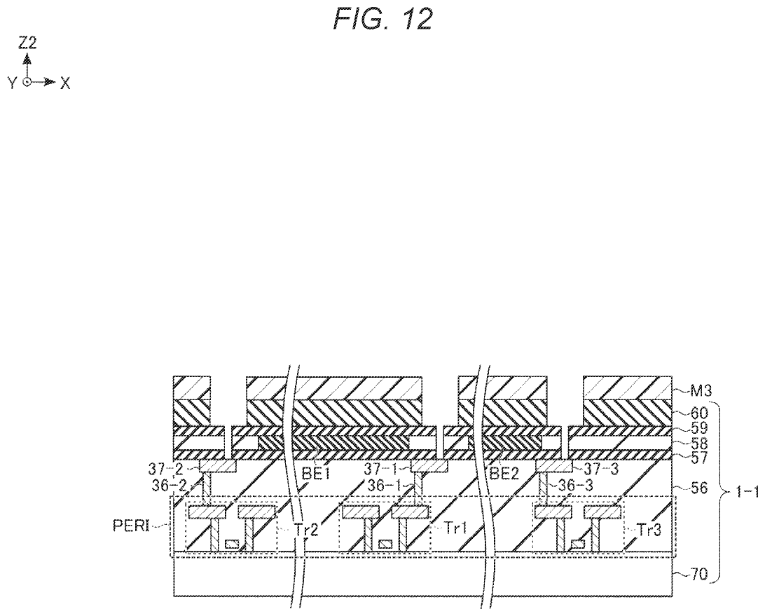

An insulating member is formed on the first surface of the insulator layer 59 including the space obtained by removal by anisotropic etching using the mask M2. Further, as shown in FIG. 12, by anisotropic etching using a mask M3 including openings corresponding to the plurality of conductor layers 39, a region in which the plurality of conductor layers 38 are to be formed and a region in which the plurality of conductor layers 39 are to be formed in the insulator layer 57 and the insulating member are collectively removed while leaving portions of the insulator layer 59 overlapping the openings when viewed in the Z-direction, for example. Thus, the portion of the insulating member after a removing process acts as the insulator layer 60. Anisotropic etching in this process is, for example, RIE. In the anisotropic etching in this process, for example, the insulator layer 59 functions as a stop film by setting the etching rate of the insulator layer 57 and the insulating member to be higher than the etching rate of the insulator layer 59. Then, the mask M3 is removed.

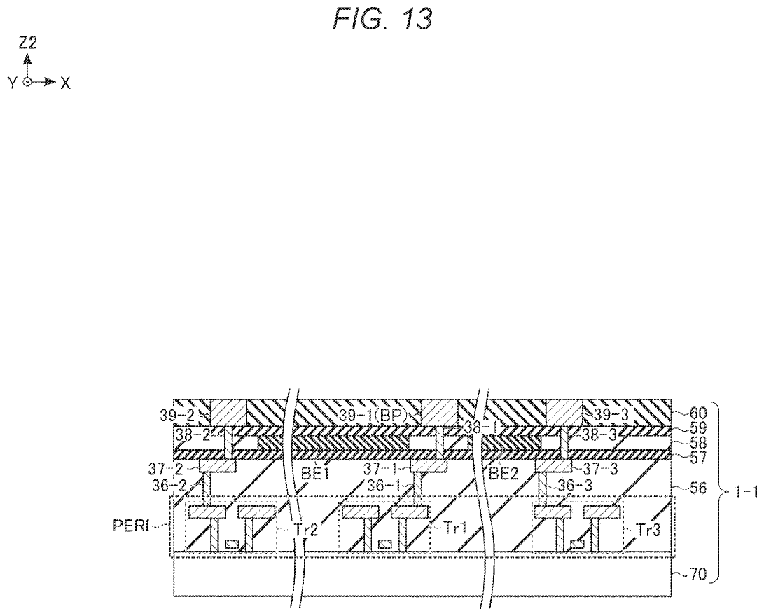

Then, as shown in FIG. 13, a plurality of conductor layers 38 and 39 are collectively formed.

Through the above processes, the circuit chip 1-1 is formed.

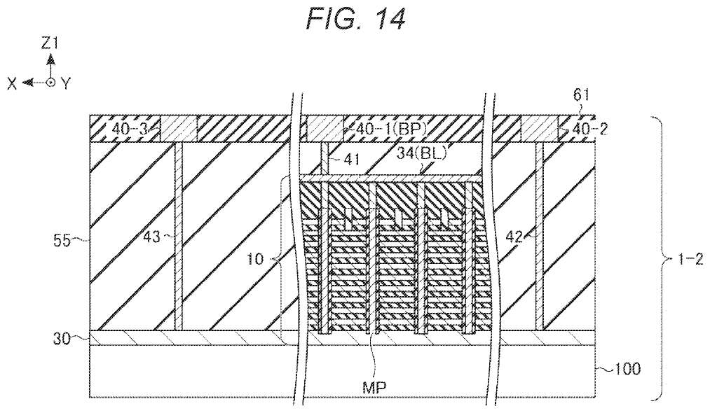

Then, as shown in FIG. 14, a conductor layer 30, a portion of the memory cell array 10 other than a conductor layer 30A, conductor layers 41 to 43, and a plurality of conductor layers 40, and insulator layers 55 and 61 are formed on the second surface of a semiconductor substrate 100. The conductor layer 30 includes portions corresponding to conductor layers 30A, 30B, and 30C. Through this process, a portion for the memory chip 1-2 is formed.

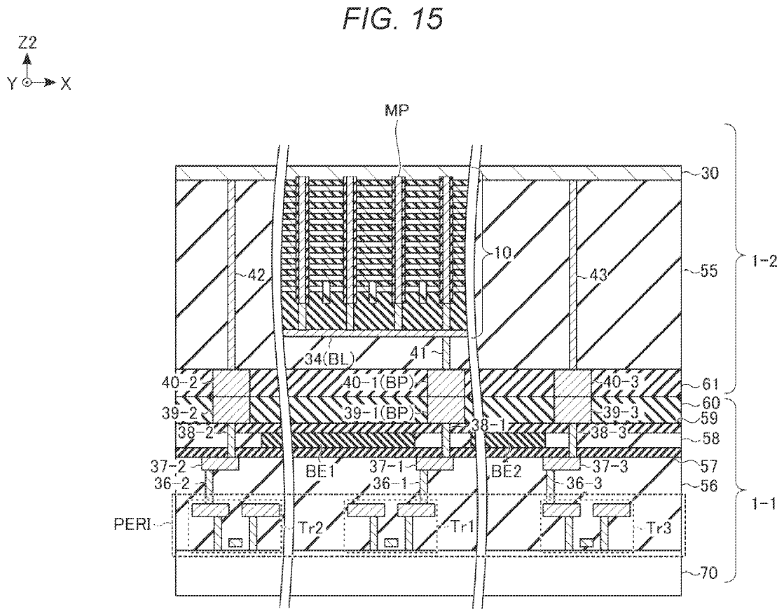

Then, as shown in FIG. 15, the circuit chip 1-1 and the memory chip 1-2 are bonded to each other by bonding processing. More specifically, the plurality of conductor layers 39 that are included at one end of the circuit chip 1-1 and function as connection pads BP, and the plurality of conductor layers 40 that are included at one end of the memory chip 1-2 and function as connection pads BP are disposed to face each other. The connection pads BP facing each other are joined by heat processing. Then, the semiconductor substrate 100 is removed.

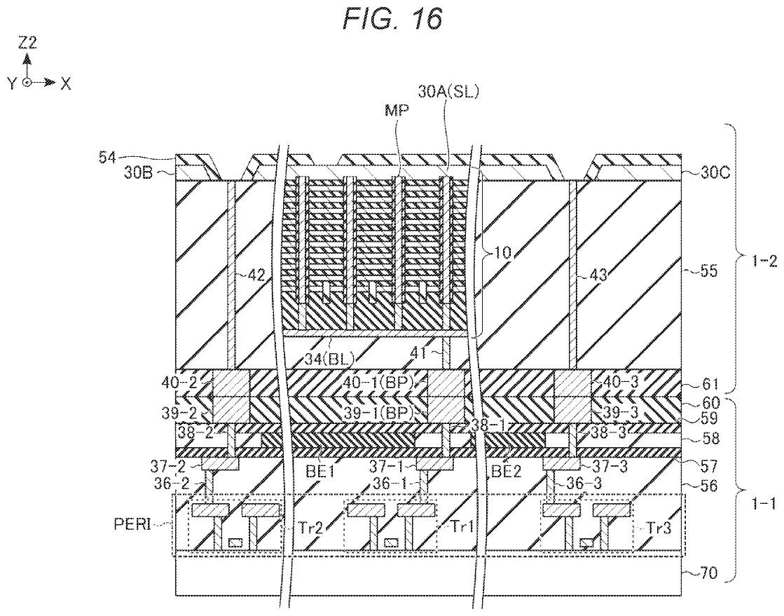

Then, the conductor layers 30A, 30B, and 30C and an insulator layer 54 are formed as shown in FIG. 16. More specifically, the conductor layer 30 is separated into the conductor layers 30A, 30B, and 30C, for example, by processing or the like using lithography and etching. An insulator is deposited on the first surfaces of the conductor layers 30A, 30B, and 30C, at a portion surrounding the conductor layers 42 and 43 on the first surface of the insulator layer 55, and on the first surfaces of the conductor layers 42 and 43. For example, by processing or the like using lithography and etching, regions in which portions C1 and C2 of a conductor layer 44A and a portion C3 of a conductor layer 44B are to be formed is removed from the deposited insulator. Thus, the insulator layer 54 is formed.

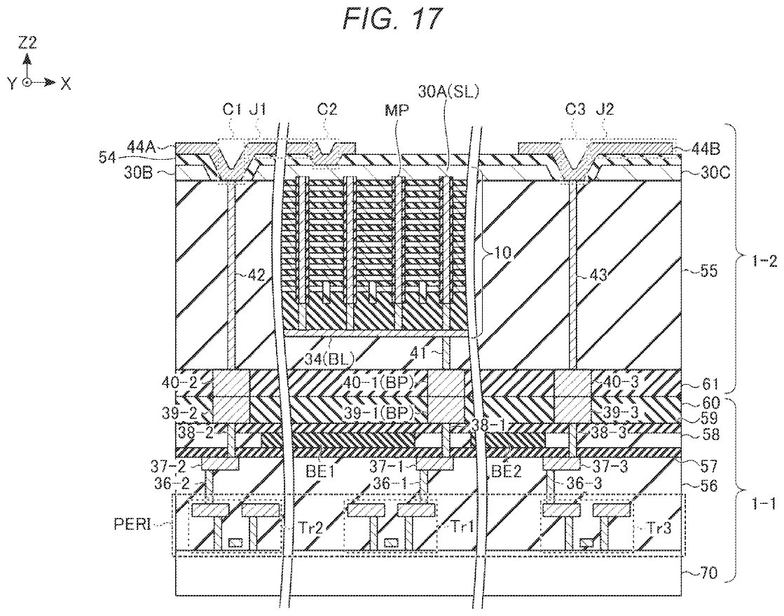

Then, as shown in FIG. 17, the conductor layers 44A and 44B are formed. More specifically, on the first surface of the insulator layer 54, on the first surfaces of the conductor layers 42 and 43, on the first surface of the conductor layer 30A, and at the portion at which the insulator layer 54 is not provided on the first surface of the insulator layer 55, the conductor layer 44 is formed to have a thickness in the Z-direction, which is substantially uniform. The formed conductor layer 44 is separated into the conductor layers 44A and 44B by, for example, processing using lithography and etching. Through this process, the portions C1, C2, and J1 of the conductor layer 44A and the portions C3 and J2 of the conductor layer 44B are formed.

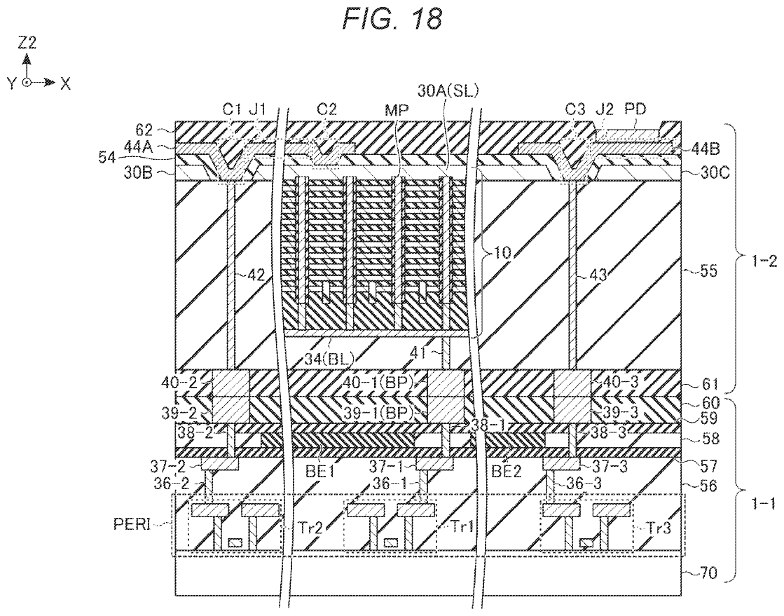

Then, as shown in FIG. 18, an electrode pad PD and an insulator layer 62 having an opening on the first surface of the electrode pad PD are formed. More specifically, first, the electrode pad PD is formed on the first surface of the portion J2. The insulator layer 62 is formed at the first end of the semiconductor storage device 1 other than a region in which the electrode pad PD is provided.

The manufacturing steps described above are merely examples, and other processing may be inserted between the manufacturing steps, or the order of the manufacturing steps may be changed. For example, since the circuit chip 1-1 and the memory chip 1-2 are formed by using different semiconductor substrates, the steps of forming the circuit chip 1-1 shown in FIGS. 7 to 13 and the steps of forming the portion for the memory chip 1-2 shown in FIG. 14 may proceed in parallel.

### 1.3 Effects

According to the embodiment, it is possible to prevent a decrease in yield of the semiconductor storage device 1.

According to the embodiment, in the circuit chip 1-1, the semiconductor storage device 1 includes the burying member BE in the same layer as the insulator layer 58 intersecting with the plurality of conductor layers 38 that are respectively in contact with the plurality of conductor layers 39 functioning as the connection pads BP. The burying member BE can be a high compressive stress member or a tensile stress member having an internal stress different from the insulator layer 58. Thus, it is possible to prevent or reduce warping of the semiconductor storage device 1. Therefore, it is possible to prevent an occurrence of defects due to warping of the semiconductor storage device 1. Thus, it is possible to prevent a decrease in the yield of semiconductor storage device 1 in manufacturing.

Additionally, due to the three-dimensional stacked structure in which a plurality of layers are stacked on a semiconductor substrate, the portion of the semiconductor storage device other than the semiconductor substrate may cause warping of the semiconductor storage device in each of the X-direction and the Y-direction. For example, processing for thinning a semiconductor substrate in a manufacturing step may cause warping of the semiconductor storage device, which was previously prevented by the semiconductor substrate before the processing, to become more noticeable. That is, since the influence of the portion of the semiconductor storage device other than the semiconductor substrate on the warping of the semiconductor storage device is relatively large, the degree of warping of the semiconductor storage device may increase. As a result, the semiconductor storage device may have an upwardly convex shape or a downwardly convex shape. Therefore, for example, a short circuit between different wirings may occur due to poor connection of the electrode pads or breakage of the insulator layer.

According to the embodiment, the semiconductor storage device 1 includes the burying member BE in the circuit chip 1-1. As a result, when a semiconductor storage device design that does not include a burying member tends to warp convexly upward, it can be possible to prevent warping of a similar semiconductor storage device 1 of an embodiment by including a burying member BE that is a high compressive stress member. Further, when a semiconductor storage device design that does not include a burying member tends to warp convexly downward, it is possible to prevent warping of a similar semiconductor storage device 1 of an embodiment including a burying member BE that is a tensile stress member.

In addition, in the semiconductor storage device 1 according to the embodiment, the burying member BE is provided within the height range where the plurality of conductor layers 38 are provided. With such a configuration, it is easier to dispose the burying member BE than, for example, if the burying member were also provided in the insulator layer 55 or in the insulator layer 56. Additionally, the wiring provided in the insulator layer 56 can be disposed to obtain an efficient electrical connection in the circuit chip 1-1 when the circuit chip 1-1 and the memory chip 1-2 are electrically connected to each other. Further, the wiring provided in the insulator layer 55 can be disposed to obtain an efficient electrical connection in the memory chip 1-2, similar to the wiring provided in the insulator layer 56. For these reasons, the wirings provided in the insulator layers 55 and 56 may be arranged in a relatively complicated or intricate manner as appropriate. Therefore, the structure and disposition of a burying member may become complicated when the burying member is being provided in the insulator layer 55 and/or when the burying member is being provided in the insulator layer 56. Thus, it may become difficult to secure a region for the burying member of this type. On the other hand, the arrangement of the plurality of conductor layers 38 is uniquely determined by the arrangement of the plurality of conductor layers 39 and 40 functioning as the connection pads BP. The connection pads BP are arranged simply compared to the wirings provided in the insulator layers 55 and 56 in order to facilitate bonding of the circuit chip 1-1 and the memory chip 1-2. For these reasons, according to the embodiment, a situation in which the structure and arrangement of the burying member BE must become complicated, or that it is difficult to provide the region for the burying member BE can be avoided.

Further, according to the embodiment, the burying member BE may overlap at least a portion of other elements of the semiconductor storage device 1 when viewed in the Z-direction. Such portions/elements may be those in which warping is more likely to occur. Thus, it is possible to more effectively prevent warping of the semiconductor storage device 1. More specifically, when the burying member BE overlaps at least a portion of the memory cell array 10 when viewed in the Z-direction, it is possible to effectively prevent warping of the semiconductor storage device 1 caused by the memory cell array 10.

### 2 Modification Examples

Various modifications of the above-described embodiment can be made. A semiconductor storage device according to certain modification examples will be described below.

### 2.1 First Modification Example

The case where the burying member BE is provided in a singular rectangular shape for each of the regions OR1 and OR2 has been described, but the embodiment is not limited to this. The semiconductor storage device 1 may be configured to include a plurality of burying members BE provided in line shape spaced apart from each other in each of the regions OR1 and OR2. In the following description, the configuration and the manufacturing method of a semiconductor storage device 1 according to a first modification example will be described focusing on the differences from the configuration and the manufacturing method of the semiconductor storage device 1 according to the embodiment.

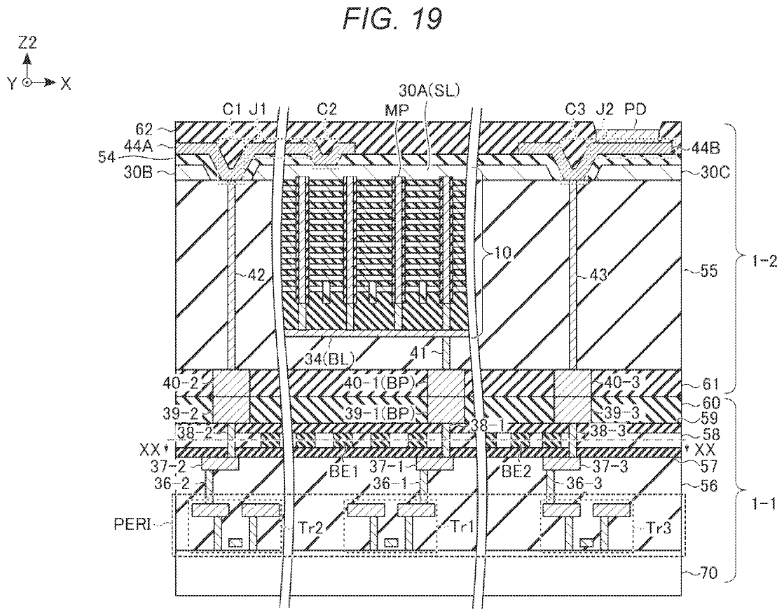

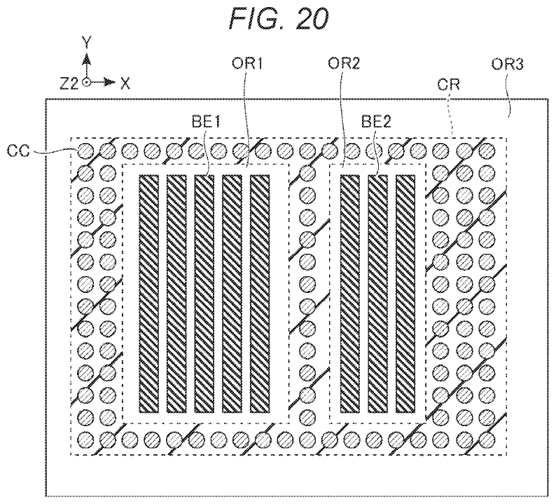

A cross-sectional structure of the semiconductor storage device 1 according to the first modification example will be described with reference to FIGS. 19 and 20. FIG. 19 corresponds to the cross-sectional structure of the semiconductor storage device shown in FIG. 4 in the embodiment. FIG. 20 is a cross-sectional view of the semiconductor storage device at a height equal to a height of XX-XX line along the Z-direction in FIG. 19, showing an example of the cross-sectional structure of the semiconductor storage device according to the first modification example in the XY plane. FIG. 19 shows a cross-sectional structure of a portion of the semiconductor storage device 1 in the XZ plane, similar to FIG. 4 in the embodiment. FIG. 20 corresponds to the cross-sectional structure of the entire semiconductor storage device 1, similar to FIG. 5 in the embodiment.

As shown in FIG. 19, the semiconductor storage device 1 includes a plurality of burying members BE1 and BE2. In the cross section shown in FIG. 19, five burying members BE1 and three burying members BE2 are shown.

As shown in FIG. 20, each of the plurality of burying members BE1 and BE2 is provided in a line shape having sides along the X-direction and the Y-direction, for example. Each of the plurality of burying members BE1 and BE2 extends in the extending direction of the word line WL. The plurality of burying members BE1 are spaced apart from each other, and the plurality of burying members BE2 are spaced apart from each other. The plurality of burying members BE1 are arranged at substantially constant intervals along the X-direction, for example. The plurality of burying members BE2 are arranged at substantially constant intervals along the X-direction, for example.

The manufacturing method of the semiconductor storage device 1 according to the first modification example is similar to the manufacturing method of the semiconductor storage device according to the embodiment except that the shape of the mask M1 in the step shown in FIG. 8 is different.

The first modification example also provides the same effect as the embodiment.

According to the first modification example, each of the plurality of burying members BE1 and BE2 extends along the extending direction of the word line WL. Thus, for example, when the semiconductor storage device 1 is likely to warp along the extending direction of the word lines WL of the memory cell array 10, it is possible to effectively prevent an increase in the degree of warping of the semiconductor storage device 1.

### 2.2 Second Modification Example

The case where each of the plurality of burying members BE1 and BE2 extends in the Y-direction has been described, but the embodiment is not limited to this. Each of the plurality of burying members BE1 and BE2 may extend in the X-direction.

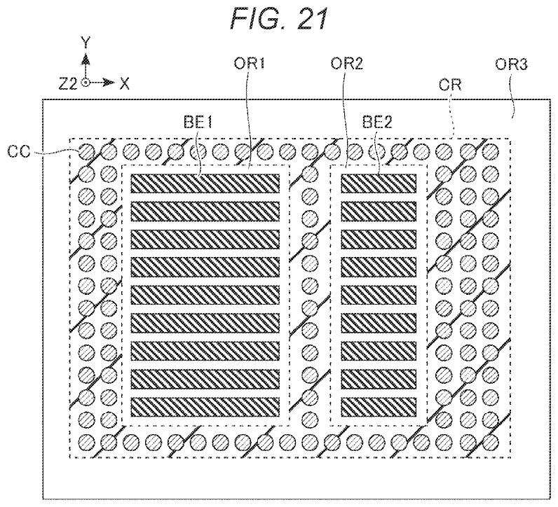

A cross-sectional structure of the semiconductor storage device 1 according to the second modification example will be described with reference to FIG. 21. FIG. 21 is a cross-sectional view showing an example of the cross-sectional structure of the semiconductor storage device according to the second modification example in the XY plane. FIG. 21 corresponds to the cross-sectional structure of the semiconductor storage device shown in FIG. 5 in the embodiment. The cross-sectional structure of the semiconductor storage device 1 according to the second modification example in the XZ plane is the same as the cross-sectional structure of the semiconductor storage device 1 according to the embodiment in the XZ plane.

As shown in FIG. 21, each of the plurality of burying members BE1 and BE2 is provided in a line shape having sides along the X-direction and the Y-direction, for example. Each of the plurality of burying members BE1 and BE2 extends in the extending direction of the bit line BL. The plurality of burying members BE1 are spaced apart from each other, and the plurality of burying members BE2 are spaced apart from each other. The plurality of burying members BE1 are arranged at substantially constant intervals along the Y-direction, for example. The plurality of burying members BE2 are arranged at substantially constant intervals along the Y-direction, for example.

The manufacturing method of the semiconductor storage device 1 according to the second modification example is similar to the manufacturing method of the semiconductor storage device according to the embodiment and the first modification example except that the shape of the mask M1 in the step shown in FIG. 8 is different.

The second modification example also provides the same effect as the embodiment.

According to the second modification example, each of the plurality of burying members BE1 and BE2 extends along the extending direction of the bit line BL. Thus, for example, when the semiconductor storage device 1 is likely to warp along the extending direction of the bit lines BL of the memory cell array 10, it is possible to effectively prevent an increase in the degree of warping of the semiconductor storage device 1.

### 2.3 Third Modification Example

The case where each burying member BE is provided in the circuit chip 1-1 has been described, but the embodiment is not limited to this. Each burying member BE may be provided in the memory chip 1-2.

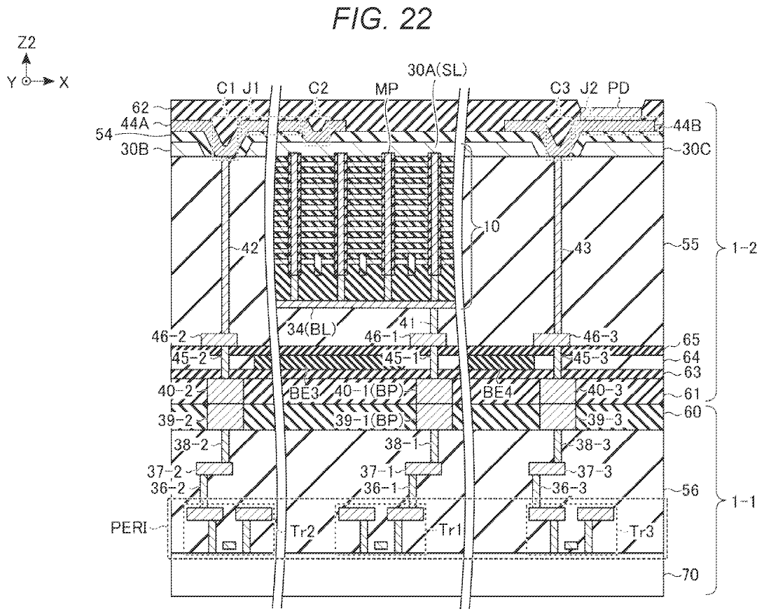

A configuration of the semiconductor storage device 1 according to the third modification example will be described with reference to FIG. 22. FIG. 22 is a cross-sectional view showing an example of a cross-sectional structure of the semiconductor storage device according to the third modification example in the XZ plane. The cross-sectional view shown in FIG. 22 corresponds to the cross-sectional view shown in FIG. 4.

A circuit chip 1-1 according to the third modification example includes a semiconductor substrate 70, a peripheral circuit PERI, a plurality of conductor layers 36, 37, 38, and 39, and insulator layers 56 and 60. That is, the circuit chip 1-1 according to the third modification example does not include the insulator layers 57 to 59 and the burying members. The structure of the circuit chip 1-1 according to the third modification example is otherwise similar to that previously described except that the insulator layers 57 to 59 and the burying member are not provided.

A memory chip 1-2 according to the third modification example includes a plurality of conductor layers 45 and 46, insulator layers 63, 64 and 65, and burying members BE3 and BE4 in addition to conductor layers 30B, 30C, 41, 42, 43, 44A, and 44B, a plurality of conductor layers 40, insulator layers 54, 55, 61, and 62, a memory cell array 10, and an electrode pad PD.

The insulator layers 63, 64, and 65 are provided in this order in the Z2 direction on the first surface of the insulator layer 61 and on the first surfaces of the plurality of conductor layers 40. Each of the insulator layers 63, 64, and 65 is formed, for example, in a plate shape extending along the XY plane. The insulator layer 63 comprises, for example, silicon nitride. The insulator layer 64 comprises, for example, silicon oxide. The insulator layer 65 comprises, for example, silicon carbide with nitrogen. A plurality of conductor layers 45 and the burying members BE3 and BE4 are provided in portions where the insulator layers 63, 64, and 65 are provided.

Each of the conductor layers 45 intersects the insulator layers 63, 64, and 65. Thus, each of the conductor layers 45 is surrounded by the respective insulator layers 63 to 65. The first surface of each of the conductor layers 45 is located at a height equal to the height of the first surface of the insulator layer 65. The second surface of each of the conductor layers 45 is located at a height equal to the height of the second surface of the insulator layer 63. The plurality of conductor layers 45 includes conductor layers 45-1, 45-2, and 45-3. The conductor layers 45-1, 45-2, and 45-3 are connected to the first surfaces of the conductor layers 40-1, 40-2, and 40-3, respectively. Each of the conductor layers 45 functions as a columnar contact.

The burying members BE3 and BE4 are provided spaced apart from each other. The first surface of each burying member BE is located at a height equal to the height of the first surface of the insulator layer 64. The second surface of each burying member BE is located at a height equal to the height of the second surface of the insulator layer 64. As described above, each conductor layer 45 is surrounded by the insulator layer 64, and thus the burying members BE3 and BE4 are provided to be spaced apart from each of the plurality of conductor layers 45.

The insulator layer 55 is provided on the first surfaces of the insulator layer 65 and on the first surface of each of the plurality of conductor layers 45. A plurality of conductor layers 46 are provided in the insulator layer 55, in addition to the conductor layers 41, 42, and 43 and a portion of the memory cell array 10.

The plurality of conductor layers 46 includes conductor layers 46-1, 46-2, and 46-3. The conductor layers 46-1, 46-2, and 46-3 are connected to the first surfaces of the conductor layers 45-1, 45-2, and 45-3, respectively.

The conductor layer 41 is provided on the first surface of the conductor layer 46-1.

The conductor layer 42 is provided on the first surface of the conductor layer 46-2.

The conductor layer 43 is provided on the first surface of the conductor layer 46-3.

The cross-sectional structure of the burying members BE3 and BE4 and the cross-sectional structure in the same layer as the burying members BE3 and BE4 are substantially the same as the cross-sectional structure of the semiconductor storage device according to the embodiment shown in FIG. 5 in the XY plane except that the burying members BE3 and BE4 are provided instead of the burying members BE1 and BE2, and not the circuit chip 1-1 but the memory chip 1-2 includes the burying members BE3 and BE4.

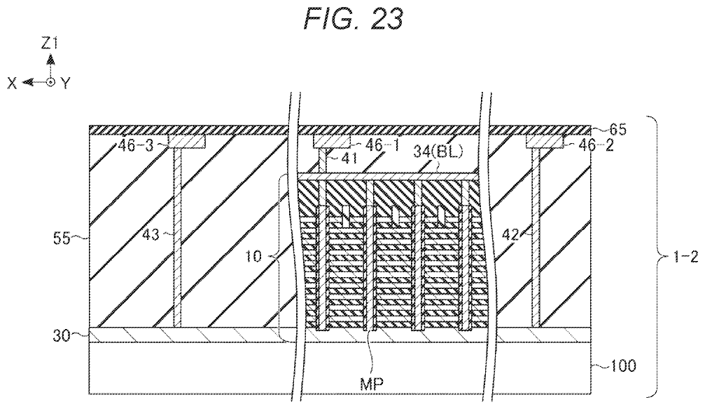

A manufacturing method of the semiconductor storage device 1 according to the third modification example will be described with reference to FIG. 23. FIG. 23 is a cross-sectional view showing an example of the manufacturing method of a memory cell array in the semiconductor storage device according to the third modification example.

In the manufacturing step of the memory chip 1-2 in the manufacturing method of the semiconductor storage device 1 according to the third modification example, as shown in FIG. 23, a conductor layer 30, a portion of the memory cell array 10 other than a conductor layer 30A, conductor layers 41 to 43, a plurality of conductor layers 46, and an insulator layer 65 are formed on the second surface of a semiconductor substrate 100.

Then, a plurality of conductor layers 40 and 45, insulator layers 61, 63, and 64, and the burying members BE3 and BE4 are respectively formed in the similar manner to the plurality of conductor layers 39 and 38, the insulator layers 60, 59, and 58, and the burying members BE1 and BE2 in the embodiment.

The manufacturing method of the circuit chip 1-1 in the third modification example is similar to the manufacturing method of the circuit chip 1-1 in the embodiment except that the insulator layers 57 to 59 and the burying members BE1 and BE2 are not formed.

The steps after the circuit chip 1-1 and the memory chip 1-2 are manufactured are substantially the same as the manufacturing method described with reference to FIGS. 15 to 18.

The third modification example also provides the same effects as those of the embodiment, the first modification example, and the second modification example. The third modification example can also be combined with another modification example. That is, the cross-sectional structure of the burying members BE3 and BE4 and the cross-sectional structure in the same layer as the burying members BE3 and BE4 may be substantially the same as the cross-sectional structure of the semiconductor storage device according to the first modification example shown in FIG. 20 in the XY plane or the cross-sectional structure of the semiconductor storage device according to the second modification example shown in FIG. 21 in the XY plane.

In addition, in the semiconductor storage device 1 according to the third modification example, the burying member BE is provided within a height range where the plurality of conductor layers 45 are provided. According to such a configuration, it is easy to dispose the burying member BE for the similar reasons explained for the semiconductor storage device according to the embodiment.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a first chip including a substrate; and
a second chip contacting the first chip, the second chip including a memory cell array including a plurality of first wiring layers spaced apart from each other in a first direction and a memory pillar that penetrates the plurality of first wiring layers in the first direction, wherein
the device includes:
a plurality of first connection pads in a boundary region between the first chip and the second chip in the first direction;
a plurality of first contacts extending in the first direction from the plurality of first connection pads;
a first insulator layer surrounding the plurality of first contacts in a first plane parallel to the substrate; and
a first member adjacent to the first insulator layer in the first plane,
the first insulator layer separating the first member from the plurality of first contacts, and
the first member having a stress value different from a stress value of the first insulator layer.

2. The semiconductor storage device according to claim 1, wherein
the plurality of first connection pads are on a first chip side of the boundary region,
a plurality of second connection pads are further included in the boundary region on a second chip side of the boundary region,
first surfaces of the first connection pads are in direct contact with the second connection pads, and
the plurality of first contacts are in contact with second surfaces of the first connection pads opposite of the first surfaces.

3. The semiconductor storage device according to claim 1, wherein
the plurality of first connection pads are on a second chip side of the boundary region,
a plurality of second connection pads are further included in the boundary region on a first chip side of the boundary region,
first surfaces of the first connection pads are in direct contact with the second connection pads, and
the plurality of first contacts are in contact with second surfaces of the first connection pads opposite of the first surfaces.

4. The semiconductor storage device according to claim 1, wherein the first member has a portion overlapping with the memory cell array along the first direction.

5. The semiconductor storage device according to claim 1, wherein the first member has a compressive stress greater than a compressive stress of the first insulator layer.

6. The semiconductor storage device according to claim 1, wherein the first member has a tensile stress.

7. The semiconductor storage device according to claim 1, wherein the first insulator layer comprises silicon oxide.

8. A semiconductor storage device, comprising:
a first chip including a substrate; and
a second chip contacting the first chip, the second chip including a memory cell array including a plurality of first wiring layers spaced apart from each other in a first direction and a plurality of memory pillars that penetrate the plurality of first wiring layers in the first direction, wherein
the device includes:
a plurality of first contacts that extend in the first direction to electrically connect the first chip and the second chip;
a first insulator layer surrounding the plurality of first contacts in a first plane parallel to the substrate; and
a plurality of first members adjacent to the first insulator layer in the first plane,
the first insulator layer separating the plurality of first members from the plurality of first contacts,
the first members extending lengthwise in a second direction parallel to the substrate spaced apart from each other in a third direction perpendicular to the first and second directions, and
the first members having a stress value different from a stress value of the first insulator layer.

9. The semiconductor storage device according to claim 8, wherein each of the plurality of first wiring layers includes wirings extending in the second direction.

10. The semiconductor storage device according to claim 8, wherein
the memory cell array further includes a second wiring layer with wirings that extend in the second direction and are electrically connected to an end of a memory pillar in the plurality of memory pillars, and
each of the plurality of first wiring layers includes wirings extending in the third direction.

11. The semiconductor storage device according to claim 8, wherein the plurality of first members have a portion overlapping with the memory cell array along the first direction.

12. The semiconductor storage device according to claim 8, wherein the first members have a compressive stress greater than a compressive stress of the first insulator layer.

13. The semiconductor storage device according to claim 8, wherein the first members have a tensile stress.

14. The semiconductor storage device according to claim 8, wherein the first insulator layer comprises silicon oxide.

15. The semiconductor storage device according to claim 8, wherein the plurality of first members are spaced from each other at a substantially equal interval in the third direction.

16. A semiconductor storage device, comprising:
a first chip including a substrate; and
a second chip contacting the first chip, the second chip including a memory cell array including a plurality of first wiring layers spaced apart from each other in a first direction and a memory pillar that penetrates the plurality of first wiring layers in the first direction, wherein
the device includes:
a plurality of first connection pads in a boundary region between the first chip and the second chip in the first direction;
a plurality of first contacts in contact with the plurality of first connection pads, each extending in the first direction;
a first insulator layer surrounding the plurality of first contacts in a first plane parallel to the substrate; and
a plurality of first members adjacent to the first insulator layer in the first plane,
the first insulator layer separating the plurality of first members from the plurality of first contacts,
the first members each extending lengthwise in a second direction parallel to the substrate in the first plane, and
the first members having a stress value different from a stress value of the first insulator layer.

17. The semiconductor storage device according to claim 16, wherein the plurality of first members have a portion overlapping with the memory cell array along the first direction.

18. The semiconductor storage device according to claim 16, wherein the first members have a compressive stress greater than a compressive stress of the first insulator layer.

19. The semiconductor storage device according to claim 16, wherein the first members have a tensile stress.

20. The semiconductor storage device according to claim 16, wherein the first insulator layer comprises silicon oxide.
